(19) United States
(12) Patent Application Publication
(10) Pub. No.: US 2023/0351079 A1
(43) Pub. Date: Nov. 2, 2023

(54) WELL CORRELATION THROUGH INTERMEDIARY WELL

(71) Applicant: Chevron U.S.A. Inc., San Ramon, CA (US)

(72) Inventors: Robert Chadwick HOLMES, Houston, TX (US); Fabien J. LAUGIER, Houston, TX (US); Ashley D. HARRIS, Houston, TX (US); Morgan David SULLIVAN, Houston, TX (US)

(21) Appl. No.: 18/027,858

(22) PCT Filed: Nov. 10, 2021
(86) PCT No.: PCT/US2021/058730

§ 371 Date: Mar. 22, 2023

Related U.S. Application Data
(60) Provisional application No. 63/113,694, filed on Nov. 13, 2020.

(51) Int. Cl. G06F 30/28; E21B 49/00; E21B 41/00

(52) U.S. Cl. CPC G06F 30/28; E21B 41/00; E21B 49/00

(57) ABSTRACT

An intermediary well may be selected for a group of wells. The intermediary well may be used as an origin point from which branching wells paths are generated to connect the group of wells through the intermediary well. A shortest path between the intermediary well and the group of wells along the branching well paths may be identified, and the group of wells may be aligned along the shortest path. Boundaries of the intermediary well may be propagated to the aligned group of wells to establish correlation between segments of the intermediary well and segments of the aligned group of wells.

### CROSS-REFERENCE TO RELATED APPLICATION

The present application claims the benefit of U.S. Provisional Application No. 63/113,694, entitled “WELL CORRELATION THROUGH INTERMEDIARY WELL,” which was filed on Nov. 13, 2020, the entirety of which is hereby incorporated herein by reference.

### FIELD

The present disclosure relates generally to the field of correlating wells within a region of interest using an intermediary well.

### BACKGROUND

Correlation of different wells using well logs may provide insights on whether and/or how different segments of the wells are linked together. Lithostratigraphic correlation that rely on pattern matching to link similar segments may result in inaccurate correlation between wells, creating a false sense of connectivity and resulting in mischaracterization of the subsurface stratigraphic framework. Additionally, manual correlation of wells may be difficult, subjective, biased, and non-repeatable.

### SUMMARY

This disclosure relates to correlating wells. Well information and/or other information may be obtained. The well information may define subsurface configuration of a group of wells within a region of interest. The group of wells may include multiple wells. An intermediary well may be selected for the group of wells. The intermediary well may have boundaries that separate segments of the intermediary well. Branching well paths may be generated. The branching well paths may connect the group of wells through the intermediary well. Origin of the branching well paths may be located at the intermediary well. A shortest path between the intermediary well and the group of wells may be identified along the branching well paths. The group of wells may be aligned along the shortest path. The boundaries of the intermediary well may be propagated to the aligned group of wells. The propagation of the boundaries of the intermediary well to the aligned group of wells may establish correlation between the segments of the intermediary well and segments of the aligned group of wells.

A system that correlates wells may include one or more electronic storage, one or more processors and/or other components. The electronic storage may store well information, information relating to wells, information relating to group of wells, information relating to region of interest, information relating to intermediary well, information relating to branching well paths, information relating to shortest path, information relating to alignment of wells, information relating to propagation of boundaries of well, information relating to correlation between wells, and/or other information.

The processor(s) may be configured by machine-readable instructions. Executing the machine-readable instructions may cause the processor(s) to facilitate correlating wells. The machine-readable instructions may include one or more computer program components. The computer program components may include one or more of a well information component, an intermediary well component, a branching well path component, a shortest path component, an alignment component, a propagation component, and/or other computer program components.

The well information component may be configured to obtain well information and/or other information. The well information may define subsurface configuration of a group of wells within a region of interest. The group of wells may include multiple wells. In some implementations, the well information may include one or more well logs for individual wells in the group of wells. In some implementations, the well log(s) for the individual wells may be normalized based on a log scaling and/or other information.

The intermediary well component may be configured to select an intermediary well for the group of wells. The intermediary well may have boundaries that separate segments of the intermediary well. In some implementations, individual wells in the group of wells may be selected as the intermediary well. Separate scenarios of correlation may be established for different selections of the individual wells in the group of wells as the intermediary well. In some implementations, a pseudo well representative of the region of interest may be selected as the intermediary well.

In some implementations, the pseudo well representative of the region of interest may be generated based on combination of the subsurface configuration of the group of wells and/or other information. The generation of the pseudo well based on the combination of the subsurface configuration of the group of wells may include: connecting the individual wells in the group of wells based on a distance threshold and/or other information; determining dynamic time warping paths for individual pairs of the connected wells based on the normalized well log(s) for the individual wells and/or other information; determining shifts of the individual wells based on the dynamic time warping paths and/or other information; aligning the individual wells based on the shifts of the individual wells and/or other information; and combining the subsurface configuration of the aligned wells to determine pseudo subsurface configuration of the pseudo well.

In some implementations, the distance threshold may be adjusted to minimize number of connections within the group of wells without leaving any well isolated. In some implementations, the distance threshold may be adjusted to establish at least a minimum number of connections for the individual wells in the group of wells.

In some implementations, the pseudo well may be positioned at a centroid position of the group of wells.

The branching well path component may be configured to generate branching well paths connecting the group of wells through the intermediary well. Origin of the branching well paths may be located at the intermediary well.

The shortest path component may be configured to identify a shortest path between the intermediary well and the group of wells along the branching well paths.

The alignment component may be configured to align the group of wells along the shortest path.

The propagation component may be configured to propagate the boundaries of the intermediary well to the aligned group of wells. The propagation of the boundaries of the intermediary well to the aligned group of wells may establish correlation between the segments of the intermediary well and segments of the aligned group of wells.

These and other objects, features, and characteristics of the system and/or method disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a,” “an,” and “the” include plural referents unless the context clearly dictates otherwise.

### BRIEF DESCRIPTION OF THE DRAWINGS

FIG. 1 illustrates an example system that correlates wells.

FIG. 2 illustrates an example method for correlating wells.

FIG. 3 illustrates an example group of wells.

FIG. 4 illustrates an example normalization of a well log.

FIG. 5 illustrates an example Continuous Wavelet Transform plot for boundary identification.

FIG. 6 illustrates example connections between wells.

FIG. 7 illustrates an example correlation between two well logs.

FIG. 8 illustrates example generation of a pseudo well representative of a region of interest.

FIG. 9 illustrates an example positioning of a pseudo well at a centroid position of a group of wells.

FIG. 10 illustrates example branching well paths connecting a group of wells through an intermediary well.

FIG. 11 illustrates an example propagation of boundaries of an intermediary well to other wells.

FIG. 12 illustrates an example correlation scenario.

### DETAILED DESCRIPTION

The present disclosure relates to correlating wells. An intermediary well may be selected for a group of wells. The intermediary well may be used as an origin point from which branching wells paths are generated to connect the group of wells through the intermediary well. A shortest path between the intermediary well and the group of wells along the branching well paths may be identified, and the group of wells may be aligned along the shortest path. Boundaries of the intermediary well may be propagated to the aligned group of wells to establish correlation between segments of the intermediary well and segments of the aligned group of wells.

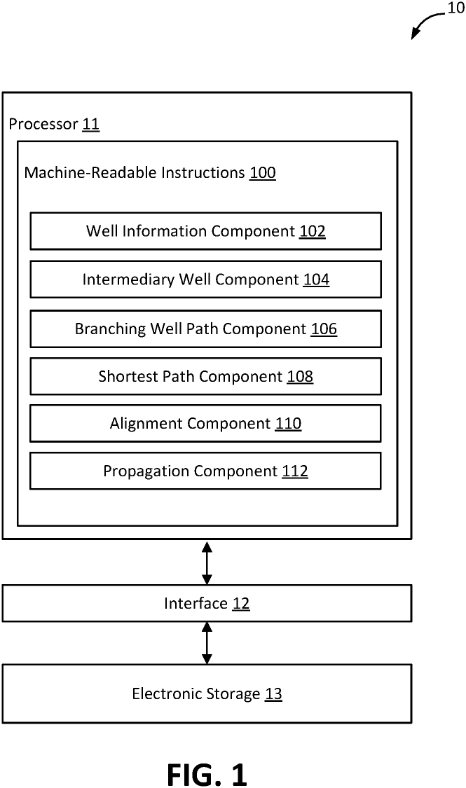

The methods and systems of the present disclosure may be implemented by and/or in a computing system, such as a system 10 shown in FIG. 1. The system 10 may include one or more of a processor 11, an interface 12 (e.g., bus, wireless interface), an electronic storage 13, and/or other components. Well information and/or other information may be obtained by the processor 11. The well information may define subsurface configuration of a group of wells within a region of interest. The group of wells may include multiple wells. An intermediary well may be selected for the group of wells by the processor 11. The intermediary well may have boundaries that separate segments of the intermediary well. Branching well paths may be generated by the processor 11. The branching well paths may connect the group of wells through the intermediary well. Origin of the branching well paths may be located at the intermediary well. A shortest path between the intermediary well and the group of wells may be identified along the branching well paths by the processor 11. The group of wells may be aligned along the shortest path. The boundaries of the intermediary well may be propagated to the aligned group of wells by the processor 11. The propagation of the boundaries of the intermediary well to the aligned group of wells may establish correlation between the segments of the intermediary well and segments of the aligned group of wells.

A critical step in the analysis of a subsurface region (e.g., subsurface geology) is the stratigraphic correlation of well log data. Stratigraphic correlation, or the explicit linkage of patterns across multiple wells, may be used to separate and relate subsurface packages in terms of stratigraphic successions at scales ranging from individual depositional events to major divisions in geologic time. This work may be performed manually by subject matter experts in stratigraphy, making it both time-consuming and fundamentally based on a multitude of decisions by those individuals that are difficult, if not impossible, to fully capture and/or reproduce.

Automated correlation of well logs attempts to perform correlation using statistical analyses and pattern matching methods. Many automated correlation techniques focus on lithostratigraphic correlation of well logs and/or cores. These techniques correlate wells by searching for the segments in well logs and/or cores with highly similar patterns and generate correlations by simply linking these segments together. Lithostratigraphic correlations have been shown to create a false sense of connectivity, sometimes crossing depositional time boundaries entirely and resulting in a mischaracterization of the subsurface stratigraphic framework.

Additionally, well correlation may be highly dependent on the well that is used to start the pattern identification and matching process. Manual correlation may involve a time-consuming initial review of the well data available, false-starts at correlations that are later abandoned, or simply a subjective decision to anchor on one particular well’s log(s) as the most representative for the collection of wells being correlated and pursuing the correlation process from that well. If the datasets comprise numerous wells (e.g., hundreds to thousands of wells), it is unfeasible for individuals to process this information, identify all possible patterns at various scale across these wells, and to perform correlation within a desired time-frame. Collectively these challenges cause well log correlations to be subjective, biased, and non-repeatable. As a result, well log data and the spatial variability between wells may not be appropriately assessed, resulting in uncertainty in predicting subsurface properties (e.g., reservoir properties) at undrilled locations and for subsurface business decisions.

Present disclosure solves these problems by utilizing an intermediary well to automatically correlate wells within a region of interest. The intermediary well may be (1) a type well that is representative of the region of interest, or (2) individual wells in the group of wells. The type well may represent regional log trend, which may be used to identify regionally important well segment boundaries. The type well provides a stable starting point to guide multi-well stratigraphic repositioning and correlation. Use of the individual wells as the intermediary well enables generation of multiple scenarios of correlation for the group of wells.

The use of the intermediary well enables correlation of well logs that are fully-automated, consistent, and repeatable. The present disclosure increases the speed and objectivity of subsurface correlation, and provides a quantitative approach to assessing the spatial variability and correlation uncertainty of subsurface well log data. Generation of correlation scenarios using a type log created from the spectrum of well logs provides a mechanism to guide correlation using all information presented across the wells. Moreover, the ability to determine the appropriate number of boundaries to match manual subject matter expert work provides a rapid mechanism to assess the quality of the resulting boundaries within wells. By rapidly assessing the range of correlation scenarios that are possible across wells and at multiple vertical scales, it is possible to more robustly characterize the spatial and vertical distribution of rock properties represented by well logs. Collectively, these advances support improved, and accelerated decisions related to landing zone/reservoir targeting, drilling locations, development strategy.

Referring back to FIG. 1, the electronic storage 13 may be configured to include electronic storage medium that electronically stores information. The electronic storage 13 may store software algorithms, information determined by the processor 11, information received remotely, and/or other information that enables the system 10 to function properly. For example, the electronic storage 13 may store well information, information relating to wells, information relating to group of wells, information relating to region of interest, information relating to intermediary well, information relating to branching well paths, information relating to shortest path, information relating to alignment of wells, information relating to propagation of boundaries of well, information relating to correlation between wells, and/or other information.

The processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 100 to facilitate correlating wells. The machine-readable instructions 100 may include one or more computer program components. The machine-readable instructions 100 may include one or more of a well information component 102, an intermediary well component 104, a branching well path component 106, a shortest path component 108, an alignment component 110, a propagation component 112, and/or other computer program components.

The well information component 102 may be configured to obtain well information and/or other information. Obtaining well information may include one or more of accessing, acquiring, analyzing, creating, determining, examining, generating, identifying, loading, locating, opening, receiving, retrieving, reviewing, selecting, storing, utilizing, and/or otherwise obtaining the well information. The well information component 102 may obtain well information from one or more locations. For example, the well information component 102 may obtain well information from a storage location, such as the electronic storage 13, electronic storage of a device accessible via a network, and/or other locations. The well information component 102 may obtain well information from one or more hardware components (e.g., a computing device, a component of a computing device) and/or one or more software components (e.g., software running on a computing device). Well information may be stored within a single file or multiple files.

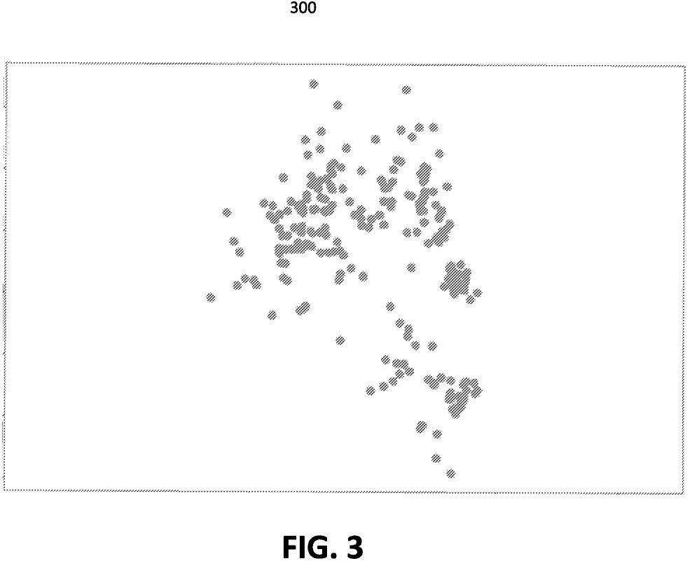

The well information may define subsurface configuration of a group of wells within a region of interest. A region of interest may refer to a region of earth that is of interest in correlating wells. For example, a region of interest may refer to a subsurface region (a part of earth located beneath the surface/located underground) for which well correlation is desired to be performed. A group of wells may include multiple wells. A group of wells may refer to wells that are located within the region of interest. A group of wells may refer to some or all of the wells that are located within the region of interest. In some implementations, a group of wells may include wells that are representative of the region of interest. FIG. 3 illustrates an example group of wells 300. Individual dots/circles in the group of wells 300 may represent a well in the region of interest.

Subsurface configuration of a well may refer to attribute, quality, and/or characteristics of the well. Subsurface configuration of a well may refer to type, property, and/or physical arrangement of materials (e.g., subsurface elements) within the well and/or surrounding the well. Examples of subsurface configuration may include types of subsurface materials, characteristics of subsurface materials, compositions of subsurface materials, arrangements/configurations of subsurface materials, physics of subsurface materials, and/or other subsurface configuration. For instance, subsurface configuration may include and/or define types, shapes, and/or properties of materials and/or layers that form subsurface (e.g., geological, petrophysical, geophysical, stratigraphic) structures. In some implementations, subsurface configuration of a well may be defined by values of one or more subsurface properties as a function of position within the well. A subsurface property may refer to a particular attribute, quality, and/or characteristics of the well.

The well information may define subsurface configuration of a group of wells by including information that describes, delineates, identifies, is associated with, quantifies, reflects, sets forth, and/or otherwise defines one or more of content, quality, attribute, feature, and/or other aspects of the subsurface configuration of the group of wells. For example, the well information may define subsurface configuration of a well by including information that makes up the content of the well and/or information that is used to identify/determine the content of the wells. In some implementations, the well information may include one or more well logs and/or associated information for individual wells in the group of wells. The well information may include a single well log or a suite of well logs for individual wells in the group of wells. For instance, the well information may include one or more well logs (of natural well, of virtual well), information determined/extracted from one or more well logs (e.g., of natural well, or virtual well), information determined/extracted from one or more well cores (e.g., of natural well, or virtual well), and/or other information. For example, the well information may include one or more well logs relating to one or more properties of a well, such as rock types, layers, grain sizes, porosity, and/or permeability of the well at different positions within the well. Other types of well information are contemplated.

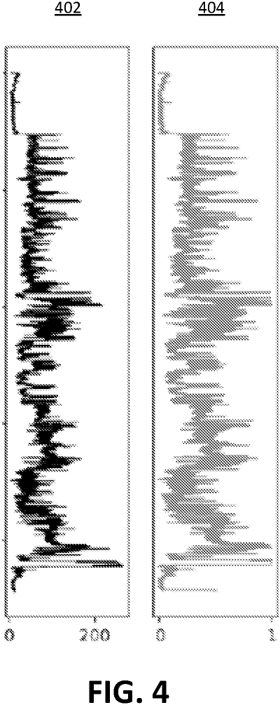

In some implementations, the well log(s) for the individual wells may be normalized based on a log scaling and/or other information. Individual well logs may be normalized to themselves. The type of normalization that is performed may depend on the scale of the well log. For example, linearly-scaled logs (e.g., gamma ray logs) may be normalized from value of zero to one based on threshold upper and lower quantiles. Non-linearly-scaled logs (e.g., deep resistivity logs) may be transformed/approximated to linear space, and then normalized from value of zero to one by the same/similar means. In some implementations, Gaussian transformation may be applied to a well log to change distribution of values within a target interval. FIG. 4 illustrates an example normalization of a well log. In FIG. 4, original well log 402 may be transformed into a normalized well log 404 so that the values of the normalized well log 404 ranges between zero and one.

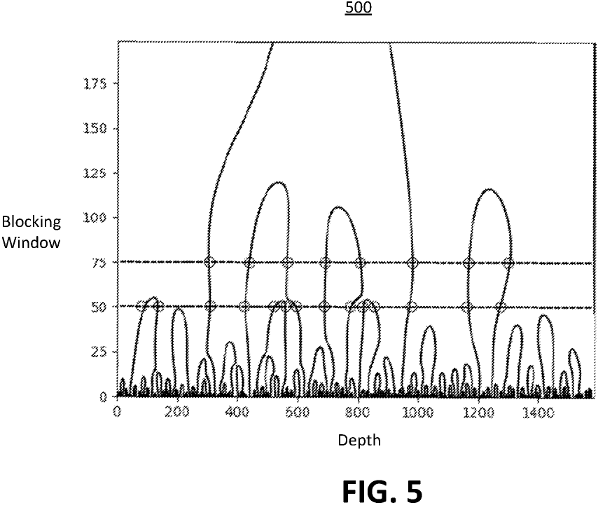

Normalization of the well logs may prepare the well logs for Continuous Wavelet Transform (CWT). The CWT may be performed on the normalized well logs based on an array of blocking windows (operator widths), and/or other information. The CWT may generate a multi-dimensional array of results. The CWT may be used to identify boundaries within individual wells. FIG. 5 illustrates an example Continuous Wavelet Transform plot 500 for boundary identification. Identified boundaries are shown as circles in the Continuous Wavelet Transform plot 500. Continuous Wavelet Transform plot 500 may show how CWT groups parts of the well log into distinct/unique segments.

Different numbers and different locations of boundaries may be identified within a well/well log based on different sizes of blocking windows. For example, use of the value 75 for the blocking window may result in identification of 8 boundaries (plus a top and a base). Use of the value 50 for the blocking window may result in identification of 14 boundaries (plus a top and a base).

The intermediary well component 104 may be configured to select an intermediary well for the group of wells. An intermediary well may refer to a well through which the group of wells may be correlated. An intermediary well may refer to a well through which wells in the group of wells may be connected for correlation analysis. The intermediary well may have boundaries that separate segments of the intermediary well. The location of the boundaries may be defined in terms of geologic space and/or geologic time.

In some implementations, the boundaries in the intermediary well may be identified based on the CWT. For example, the number and/or location of boundaries in the intermediary well may be identified based on the CWT. The CWT may be performed on a single log for the intermediary well and/or on a suite of logs (multiple logs) for the intermediary well. In some implementations, the value of the blocking windows (size of blocking window) may be set before applying it to the CWT to identify boundaries. In some implementations, the value of the blocking windows may be modified to identify a desired number of boundaries. Same or different values of the blocking windows may be used for different well logs. Individual boundaries may be associated with a depth value (spatial value, temporal value), and the depth value may correspond to a location in the well log(s) where one or more significant changes occur.

In some implementations, other/additional analysis of the well log(s) may be used to identify boundaries in the intermediary well. For example, boundaries may be identified based on changes in the well log(s) that exceed one or more threshold values. Boundaries may be identified based on a blocking analysis of one or more properties of the well log(s) (e.g., frequency changes in a spectrogram, running average). Boundaries may be identified based on a seasonal decomposition of the well log(s). Use of other boundary identification techniques are contemplated.

In some implementations, individual wells in the group of wells may be selected as the intermediary well. A particular well may be selected as the intermediary well to determine correlation between the group of wells. That is, each well in the group of wells may be selected as the intermediary well, with the techniques described herein repeated for different selections of the individual wells. Separate scenarios of correlation may be established for different selections of the individual wells in the group of wells as the intermediary well. Use of different wells in the group of wells as the intermediary well may provide different correlation results between the group of wells. Selection of an individual well in the group of wells as the intermediary well may bias the correlation of wells based on the subsurface configuration/boundaries identified in the individual well.

In some implementations, a pseudo well representative of the region of interest may be selected as the intermediary well. A pseudo well may be referred to as a type well. A pseudo well may refer to a well simulated using multiples wells in the group of wells. A pseudo well may refer to a well that is simulated within the region of interest. A pseudo well may have pseudo (simulated) subsurface configuration, which may be determined based on the subsurface configuration of multiple wells in the group of wells. The subsurface configuration of multiple wells in the group of wells may be combined to generate the pseudo subsurface configuration of the pseudo well. The pseudo subsurface configuration of the pseudo well may be representative of variations of subsurface configuration in the multiple wells.

In some implementations, the pseudo well representative of the region of interest may be generated based on combination of the subsurface configuration of the group of wells and/or other information. Combining the subsurface configuration of the group of wells may include combining the subsurface configuration of some or all the wells in group of wells. In some implementations, the generation of the pseudo well based on the combination of the subsurface configuration of the group of wells may include: (1) connecting the individual wells in the group of wells; (2) determining dynamic time warping paths for individual pairs of the connected wells; (3) determining shifts of the wells; (4) aligning the wells; and (5) combining the subsurface configuration of the aligned wells.

Individual wells in the group of wells may be connected based on a distance threshold and/or other information. Wells that are within the distance threshold (e.g., less than the distance threshold; equal or less than the distance threshold) may be connected. The wells may be connected to form a graph of wells. The graph of wells may include nodes representing the wells and edges representing connections between pairs of wells. The value of the distance threshold (e.g., lateral/geographic distance threshold) may be selected to control the connectivity of wells in the group of wells. Wells that are not within the distance threshold may not be compared/correlated for generation of the pseudo well.

In some implementations, the distance threshold may be manually set (e.g., user-defined value, default value). In some implementations, the distance threshold may be adjusted to minimize number of connections within the group of wells without leaving any well isolated. The value of the distance threshold may be automatically adjusted to the smallest value that results in all wells being connected to at least one other well. In some implementations, the distance threshold may be adjusted to establish at least a minimum (desired) number of connections for the individual wells in the group of wells. The value of the distance threshold may be automatically adjusted so that all wells are connected at least a minimum (desired) number of wells. In some implementations, the distance threshold may be adjusted based on spatial distribution of wells. The distance threshold may be adjusted based on where a well is located within the region of interest and/or based on clustering of wells in the region of interest. Use of other criteria to adjust the value of the distance threshold are contemplated.

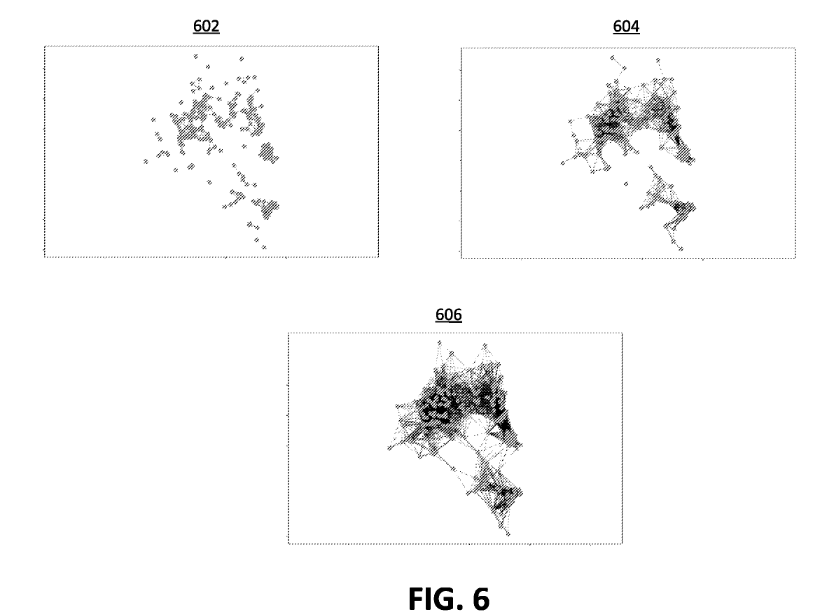

FIG. 6 illustrates example connections between wells. Scenarios 602, 604, 606 may illustrate different connectivity of wells in a group of wells based on different distance thresholds. The distance threshold may be the smallest in the scenario 602 and largest in the scenario 606. In the scenario 602, the (smallest) distance threshold may result in some of the wells being connected and some of the wells being isolated (not connected to any other well). In the scenario 604, the (middle) distance threshold may result in all but one of the wells being connected, and a single well being isolated. In the scenario 606, the (largest) distance threshold may result in all of the wells being connected, with an individual well having connections to more wells than in the scenario 604.

Dynamic time warping paths for individual pairs of the connected wells may be determined based on the well information for the individual wells and/or other information. For example, dynamic time warping paths for individual pairs of the connected wells may be determined based on the normalized well log(s) for the individual wells and/or other information. Dynamic time warping paths may be determined for those wells that have been connected together using the distance threshold. For example, a group of wells including three wells A, B, and C. Based on a distance threshold, wells A and B may be connected, wells B and C may be connected, and wells A and C may be connected. Dynamic time warping paths may be determined for well A-B pair, well B-C well, and well A-C well. Referring to FIG. 6, dynamic time warping paths may be determined for individual edges on the graph of wells.

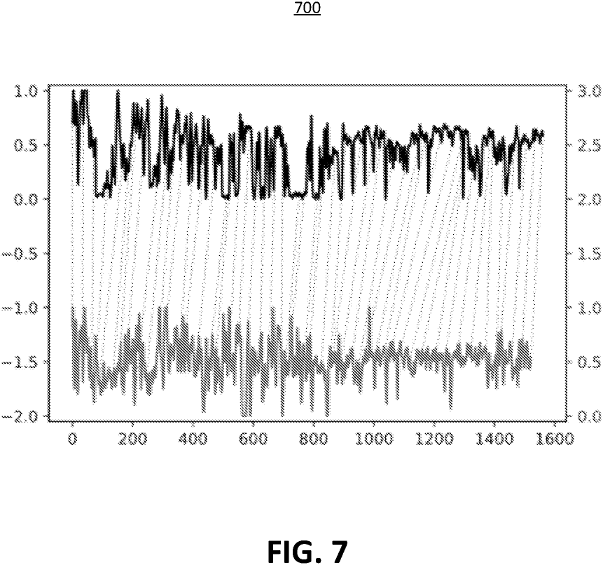

In some implementations, the determination of a dynamic time warping path for a well-to-well connection may include calculation of an optimized dynamic time warping path for the well-to-well connection. The optimized dynamic time warp path may include indices that align the corresponding well logs at the least cost. The dynamic time warping path may be used to find the (best) correlation (e.g., best alignment of well logs) between individual pairs of connected wells. FIG. 7 illustrates an example correlation 700 between two well logs. The correlation 700 may show values of two well logs, with the lines showing how a point in one well log maps to a point in the other well log.

Shifts of the wells in the group of wells may be determined based on the dynamic time warping paths and/or other information. Determining shifts of the wells may include calculating relative depth shifts for individual wells (relative depth shift for a well to a connected well to align the matching segments from the dynamic time warping paths, and using the relative depth shifts to calculate the absolute depth shift needed to align the wells. In some implementations, the shifts of the wells may be determined using a conjugate gradient optimization method to align all well pairs in a global “Relative Geologic Time” (RGT) solution. The relative shifts calculated from the dynamic time warping paths may be modified into relative geologic time.

The wells in the group of wells may be aligned based on the shifts of the individual wells and/or other information. The wells may be aligned in the RGT solution using the relative shifts calculated from the dynamic time warping paths/absolute shifts calculated from the relative shifts. The alignment of the wells may include shifting of the wells so that correlated segments of the wells are aligned. The conjugate gradient optimization method may take into account shifts for individual pairs of wells to produce a global solution in which all the wells are hung from the same datum and have consistent shifts relative to each other. The wells may be shifted so that they are consistent at all RGT values to create alignment.

The subsurface configuration of the aligned wells may be combined to determine pseudo subsurface configuration of the pseudo well. Combining subsurface configuration of the aligned wells may include uniting, merging, fusing, blending, consolidating, and/or otherwise combining the subsurface configuration of the aligned wells. For example, combining subsurface configuration of the aligned wells may include averaging (e.g., simple averaging, weighted averaging with higher weights given to more representative well log) values of the well logs across the aligned wells. Other combinations of subsurface configuration of the aligned wells are contemplated.

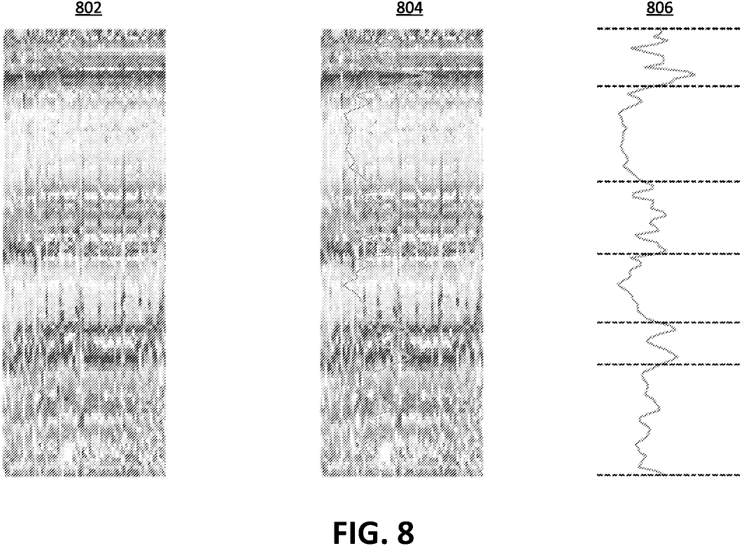

FIG. 8 illustrates example generation of a pseudo well representative of a region of interest. FIG. 8 includes a chronostratigraphic plot 802, a pseudo well plot 804, and a pseudo well boundary plot 806. The chronostratigraphic plot 802 may include visual representation of the subsurface configuration (e.g., values of well logs) of aligned wells. Alignment of the wells may include the correlated segments of the wells/well logs being placed adjacent to each other. The subsurface configuration of the aligned wells may be combined across the wells to generate the pseudo well plot 804. The combination of the subsurface configuration of the aligned wells may preserve key characteristics of the wells while removing irregularities, anomalies, jitter, and/or noise.

The pseudo well plot 804 may include visual representation of the subsurface configuration of aligned wells and a visual representation of the pseudo subsurface configuration of the pseudo well (e.g., values of a pseudo well log). The pseudo subsurface configuration of the pseudo well may be referred to as a type curve. The pseudo subsurface configuration of the pseudo well may be representative of the region of interest. The pseudo subsurface configuration of the pseudo well may represent important/key characteristics of the wells within the group of wells.

Boundaries in the pseudo well may be identified based on the pseudo subsurface configuration of the pseudo well and/or other information. For example, CWT may be used on the pseudo subsurface configuration (pseudo well log, type curve) to identify number and/or location of boundaries in the pseudo well. Use of other boundary identification techniques are contemplated. The pseudo well boundary plot 806 may show example locations of boundaries in the pseudo well as dotted lines. Adjacent boundaries may define pseudo segments within the pseudo well. The boundaries in the pseudo well may be used to correlate the wells in the group. Segments in the wells of the well groups may be correlated with the pseudo segments within the pseudo well via propagation of the boundaries in the pseudo well to the other wells.

The pseudo well may be positioned within the region of interest. The position of the pseudo well within the region of interest maya be determined manually and/or automatically. For example, the pseudo well may be positioned at a user-specified position within the region of interest. As another example, the pseudo well may be positioned at a centroid position of the group of wells. The centroid position of the group of wells may refer to a position corresponding to the center of mass of the group of wells. For example, the centroid position of the group of wells may be determined to be the average X and average Y wellhead coordinates for all wells in the group of wells. In some implementations, one or more well locations may be weighed differently (e.g., weighed more, less) than other well locations for determination of the centroid position. For example, the locations of wells from which more information/more valuable information/more representative information was retrieved may be weighed more than locations of other wells. Locations of wells in a particular area within the region of interest may be weighted more than locations of wells in other area(s). Other positions of pseudo well within the region of interest are contemplated.

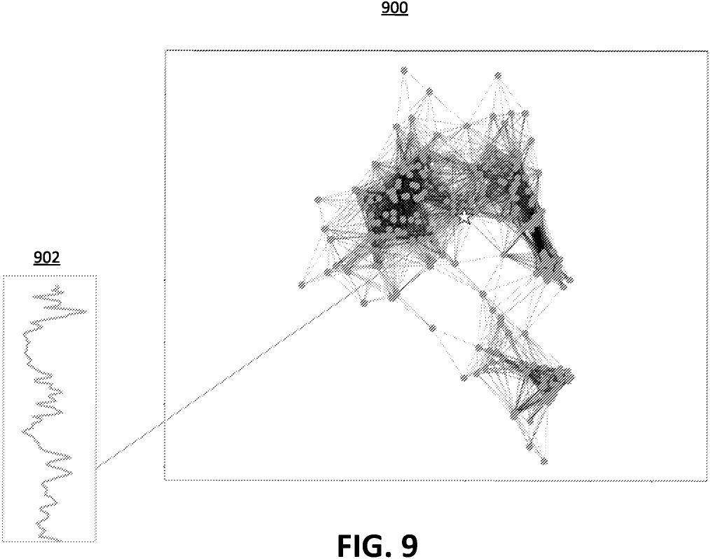

FIG. 9 illustrates an example positioning of a pseudo well at a centroid position of a group of wells 900. Positioning the pseudo well at the centroid position may result in a well having pseudo subsurface configuration/type curve 902 being placed at the centroid position of the group of wells 900.

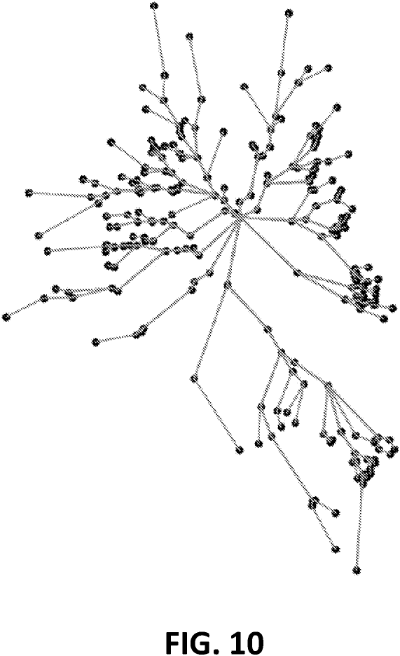

The branching well path component 106 may be configured to generate branching well paths connecting the group of wells through the intermediary well. Origin of the branching well paths may be located at the intermediary well. The branching well paths may refer to paths that branches out from the intermediary well to connect the wells in the group of wells. The branching well paths may include paths that traverse through neighboring wells. The branching well path component 106 may preferentially generate the branching well paths so that they pass through wells in the same locality while suppressing long distance well-pair connections. FIG. 10 illustrates example branching well paths connecting a group of wells through an intermediary well. In FIG. 10, the intermediary well may be located at the centroid position of the group of wells

The branching well paths may be generated through one or more triangulation techniques, such as Delaunay triangulation, that connect neighboring points while discouraging connections between distance points when intermediate points exist. The branching well paths may be generated based on an outward radial growth from the intermediary well. Other generation of branching well paths are contemplated.

The shortest path component 108 may be configured to identify a shortest path between the intermediary well and the group of wells. The shortest path may be identified along the branching well paths. The shortest path from the intermediary well to other wells in the group of wells may be identified along the branching well paths. The shortest path may refer to a path that passes through all the well while having the smallest path of travel. The shortest path may include the shortest path tree that starts at the intermediary well. The shortest path component 108 may treat the group of wells and the intermediary well as nodes in a connected graph (with branching well paths being edges of the graph), and may identify the shorted path within the connected graph. In some implementations, the shortest path may be identified based on a two-step process, where (1) the wells are triangulated so that no well (node) is inside a triangle created by connecting any three wells (e.g., Delaunay triangulation), and (2) the shortest path may be calculated using Dijkstra’s algorithm applied to well pair distance (based on X Y values of the well locations). Other means of identifying the shortest well path are contemplated.

The alignment component 110 may be configured to align the group of wells along the shortest path. Alignment of the group of wells along the shortest path may include calculation of relative depth shifts for well pairs along the shortest path. For example, well pairs along the shortest path may be collected and relative depth shifts for individual wells may be calculated using a conjugate gradient optimization method to align the pairs in a global RGT solution. The alignment of the group of wells along the shortest path may result in segments of the wells to be correlated being aligned in the RGT solution. The alignment of the group of wells along the shortest path may result in wells along the shortest path being hung from the same datum and having consistent shifts relative to each other. The wells along the shortest path may be shifted so that they are consistent at all RGT values to create alignment.

The propagation component 112 may be configured to propagate the boundaries of the intermediary well to the aligned group of wells. Propagation of the boundaries of the intermediary well to the aligned group of wells may include pushing/copying the location of the boundaries in the RGT space to the well connected along the shortest path. For example, propagation of the boundaries of the intermediary well to the aligned group of wells may include horizontal line/plane extrapolation from the intermediary well to the aligned wells in the RGT space.

The propagation of the boundaries of the intermediary well to the aligned group of wells may establish correlation between the segments of the intermediary well and segments of the aligned group of wells. Adjacent boundaries propagated to the aligned group of wells may define segments of intermediary wells that are correlated with segments of the aligned group of wells. For example, rock packages of different wells between the same top-bottom pair of propagated boundaries may be correlated. Use of pseudo well as the intermediary well to correlate the wells in the group of wells may facilitate use of the global understanding of the subsurface configuration in the region of interest (provided by the pseudo subsurface configuration of the pseudo well) in performing well correlation.

The aligned group of wells in the RGT space may be converted into spatial/temporal space to identify spatial/temporal location of correlated segments. For example, the propagated boundaries in the RGT space may be converted to true depth (in real space/in time) based on the shifts used to align the group of wells (reverse alignment of the group of wells).

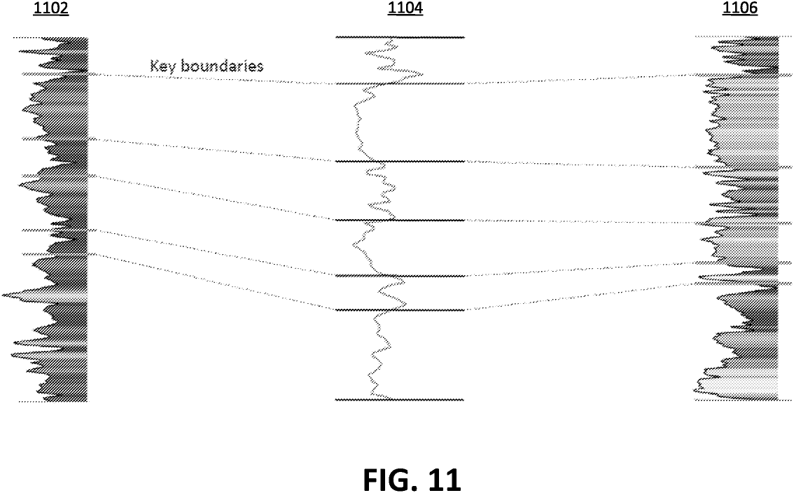

FIG. 11 illustrates an example propagation of boundaries of an intermediary well to other wells. FIG. 11 may include two wells 1102, 1106 of a group of wells and an intermediary well 1104. The boundaries of the intermediary well 1104 may be propagated to the wells 1102, 1106 to establish correlation between the segments of the intermediary well 1104 and segments of the wells 1102, 1106. Use of the intermediary well 1104 to establish correlation between the wells 1102, 1106 may enable linkage of segments that would not have been connected without the intermediary well 1104. For example, the second from the top segments of the wells 1102, 1006 may be sufficiently different that a regular dynamic time warping analysis would not correlate the two segments. These two segments may be correlated through the second from the top segment of the intermediary well 1104. That is, the segment in the wells 1102, 1106 may be sufficient similar to the segment in the intermediary well so that they are linked through the segment in the intermediary well. The use of the intermediary well 1104 enables correlations to be made between the wells 1102, 1106 that incorporate awareness of the variations in the subsurface configuration within the region of interest. The use of the intermediary well 1104 enables correlation between the wells 1102, 1105 that incorporates important features of the region of interest through the intermediary well 1104.

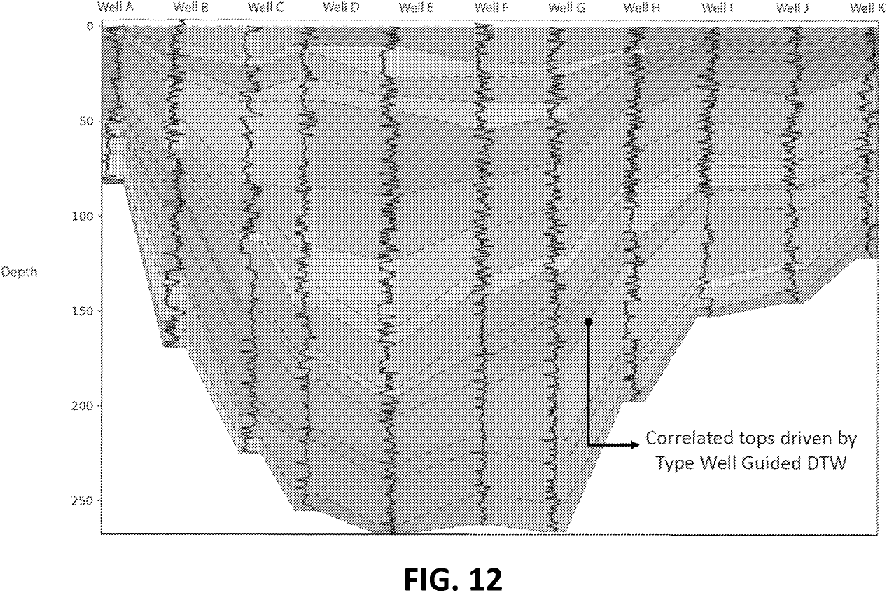

FIG. 12 illustrates an example correlation scenario for a region of interest. The wells shown in FIG. 12 may include wells along a line on branching well paths. The correlation of wells shown in FIG. 12 may be established through use of an intermediary well, such as a pseudo well representative of the region of interest. Different shading of the well segments may correspond to interpolation of average well log values of the packages between the boundaries. As shown in FIG. 12, segments of wells having varied well log values may be correlated. Correlation of wells with the use of the intermediary well may enable greater understanding of the changes in subsurface configuration of the region of interest and the connectivity between different portions of the region of interest than correlation of wells without the use of intermediary wells.

Implementations of the disclosure may be made in hardware, firmware, software, or any suitable combination thereof. Aspects of the disclosure may be implemented as instructions stored on a machine-readable medium, which may be read and executed by one or more processors. A machine-readable medium may include any mechanism for storing or transmitting information in a form readable by a machine (e.g., a computing device). For example, a tangible computer-readable storage medium may include read-only memory, random access memory, magnetic disk storage media, optical storage media, flash memory devices, and others, and a machine-readable transmission media may include forms of propagated signals, such as carrier waves, infrared signals, digital signals, and others. Firmware, software, routines, or instructions may be described herein in terms of specific exemplary aspects and implementations of the disclosure, and performing certain actions.

In some implementations, some or all of the functionalities attributed herein to the system 10 may be provided by external resources not included in the system 10. External resources may include hosts/sources of information, computing, and/or processing and/or other providers of information, computing, and/or processing outside of the system 10.

Although the processor 11 and the electronic storage 13 are shown to be connected to the interface 12 in FIG. 1, any communication medium may be used to facilitate interaction between any components of the system 10. One or more components of the system 10 may communicate with each other through hard-wired communication, wireless communication, or both. For example, one or more components of the system 10 may communicate with each other through a network. For example, the processor 11 may wirelessly communicate with the electronic storage 13. By way of non-limiting example, wireless communication may include one or more of radio communication, Bluetooth communication, Wi-Fi communication, cellular communication, infrared communication, or other wireless communication. Other types of communications are contemplated by the present disclosure.

Although the processor 11 is shown in FIG. 1 as a single entity, this is for illustrative purposes only. In some implementations, the processor 11 may comprise a plurality of processing units. These processing units may be physically located within the same device, or the processor 11 may represent processing functionality of a plurality of devices operating in coordination. The processor 11 may be separate from and/or be part of one or more components of the system 10. The processor 11 may be configured to execute one or more components by software; hardware; firmware; some combination of software, hardware, and/or firmware; and/or other mechanisms for configuring processing capabilities on the processor 11.

It should be appreciated that although computer program components are illustrated in FIG. 1 as being co-located within a single processing unit, one or more of computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 11 may be configured to execute one or more additional computer program components that may perform some or all of the functionality attributed to one or more of computer program components described herein.

The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may be a separate component within the system 10, or the electronic storage 13 may be provided integrally with one or more other components of the system 10 (e.g., the processor 11). Although the electronic storage 13 is shown in FIG. 1 as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

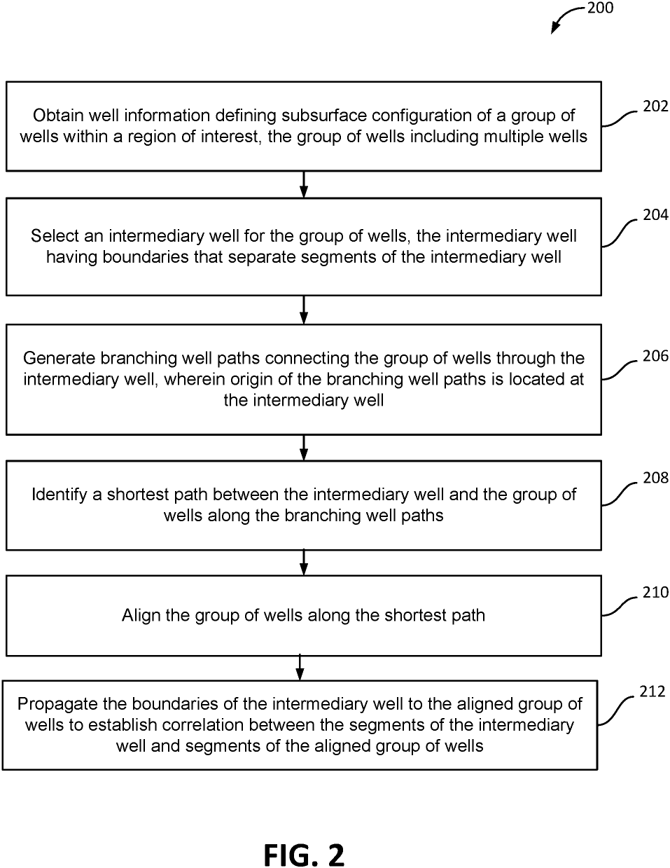

FIG. 2 illustrates method 200 for correlating wells. The operations of method 200 presented below are intended to be illustrative. In some implementations, method 200 may be accomplished with one or more additional operations not described, and/or without one or more of the operations discussed. In some implementations, two or more of the operations may occur substantially simultaneously.

In some implementations, method 200 may be implemented in one or more processing devices (e.g., a digital processor, an analog processor, a digital circuit designed to process information, a central processing unit, a graphics processing unit, a microcontroller, an analog circuit designed to process information, a state machine, and/or other mechanisms for electronically processing information). The one or more processing devices may include one or more devices executing some or all of the operations of method 200 in response to instructions stored electronically on one or more electronic storage media. The one or more processing devices may include one or more devices configured through hardware, firmware, and/or software to be specifically designed for execution of one or more of the operations of method 200.

Referring to FIG. 2 and method 200, at operation 202, well information and/or other information may be obtained. The well information may define subsurface configuration of a group of wells within a region of interest. The group of wells may include multiple wells. In some implementations, operation 202 may be performed by a processor component the same as or similar to the well information component 102 (Shown in FIG. 1 and described herein).

At operation 204, an intermediary well may be selected for the group of wells. The intermediary well may have boundaries that separate segments of the intermediary well. In some implementations, operation 204 may be performed by a processor component the same as or similar to the intermediary well component 104 (Shown in FIG. 1 and described herein).

At operation 206, branching well paths may be generated. The branching well paths may connect the group of wells through the intermediary well. Origin of the branching well paths may be located at the intermediary well. In some implementations, operation 206 may be performed by a processor component the same as or similar to the branching well path component 106 (Shown in FIG. 1 and described herein).

At operation 208, a shortest path between the intermediary well and the group of wells may be identified along the branching well paths. In some implementations, operation 208 may be performed by a processor component the same as or similar to the shortest path component 108 (Shown in FIG. 1 and described herein).

At operation 210, the group of wells may be aligned along the shortest path. In some implementations, operation 210 may be performed by a processor component the same as or similar to the alignment component 110 (Shown in FIG. 1 and described herein).

At operation 212, the boundaries of the intermediary well may be propagated to the aligned group of wells. The propagation of the boundaries of the intermediary well to the aligned group of wells may establish correlation between the segments of the intermediary well and segments of the aligned group of wells. In some implementations, operation 212 may be performed by a processor component the same as or similar to the propagation component 112 (Shown in FIG. 1 and described herein).

Although the system(s) and/or method(s) of this disclosure have been described in detail for the purpose of illustration based on what is currently considered to be the most practical and preferred implementations, it is to be understood that such detail is solely for that purpose and that the disclosure is not limited to the disclosed implementations, but, on the contrary, is intended to cover modifications and equivalent arrangements that are within the spirit and scope of the appended claims. For example, it is to be understood that the present disclosure contemplates that, to the extent possible, one or more features of any implementation can be combined with one or more features of any other implementation.

What is claimed is:

1. A system for correlating wells, the system comprising:
one or more physical processors configured by machine-readable instructions to:
obtain well information, the well information defining subsurface configuration of a group of wells within a region of interest, the group of wells including multiple wells;
select an intermediary well for the group of wells, the intermediary well having boundaries that separate segments of the intermediary well;
generate branching well paths connecting the group of wells through the intermediary well, wherein origin of the branching well paths is located at the intermediary well;
identify a shortest path between the intermediary well and the group of wells along the branching well paths;
align the group of wells along the shortest path; and
propagate the boundaries of the intermediary well to the aligned group of wells, wherein the propagation of the boundaries of the intermediary well to the aligned group of wells establishes correlation between the segments of the intermediary well and segments of the aligned group of wells.

2. The system of claim 1, wherein:
individual wells in the group of wells are selected as the intermediary well, and
separate scenarios of correlation are established for different selections of the individual wells in the group of wells as the intermediary well.

3. The system of claim 1, wherein a pseudo well representative of the region of interest is selected as the intermediary well.

4. The system of claim 3, wherein the pseudo well representative of the region of interest is generated based on combination of the subsurface configuration of the group of wells.

5. The system of claim 4, wherein the well information includes one or more well logs for individual wells in the group of wells.

6. The system of claim 5, wherein the one or more well logs for the individual wells are normalized based on a log scaling.

7. The system of claim 6, wherein the generation of the pseudo well based on the combination of the subsurface configuration of the group of wells includes:
connecting the individual wells in the group of wells based on a distance threshold;
determining dynamic time warping paths for individual pairs of the connected wells based on the one or more normalized well logs for the individual wells;
determining shifts of the individual wells based on the dynamic time warping paths;
aligning the individual wells based on the shifts of the individual wells; and
combining the subsurface configuration of the aligned wells to determine pseudo subsurface configuration of the pseudo well.

8. The system of claim 7, wherein the distance threshold is adjusted to minimize number of connections within the group of wells without leaving any well isolated.

9. The system of claim 7, wherein the distance threshold is adjusted to establish at least a minimum number of connections for the individual wells in the group of wells.

10. The system of claim 8, wherein the pseudo well is positioned at a centroid position of the group of wells.

11. A method for correlating wells, the method comprising:
obtaining well information, the well information defining subsurface configuration of a group of wells within a region of interest, the group of wells including multiple wells;
selecting an intermediary well for the group of wells, the intermediary well having boundaries that separate segments of the intermediary well;
generating branching well paths connecting the group of wells through the intermediary well, wherein origin of the branching well paths is located at the intermediary well;
identifying a shortest path between the intermediary well and the group of wells along the branching well paths;
aligning the group of wells along the shortest path; and
propagating the boundaries of the intermediary well to the aligned group of wells, wherein the propagation of the boundaries of the intermediary well to the aligned group of wells establishes correlation between the segments of the intermediary well and segments of the aligned group of wells.

12. The method of claim 11, wherein:
individual wells in the group of wells are selected as the intermediary well, and
separate scenarios of correlation are established for different selections of the individual wells in the group of wells as the intermediary well.

13. The method of claim 11, wherein a pseudo well representative of the region of interest is selected as the intermediary well.

14. The method of claim 13, wherein the pseudo well representative of the region of interest is generated based on combination of the subsurface configuration of the group of wells.

15. The method of claim 14, wherein the well information includes one or more well logs for individual wells in the group of wells.
